(19) United States
(12) Patent Application Publication
(10) Pub. No.: US 2005/0088388 A1
(43) Pub. Date: Apr. 28, 2005

(54) Imaging display apparatus

(75) Inventor: Keiichi Miyazaki, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 10/942,144

(22) Filed: Sep. 16, 2004

(30) Foreign Application Priority Data
Sep. 18, 2003 (JP) P.2003-325388

(51) Int. Cl. G09G 3/36; G03F 3/10

(52) U.S. Cl. 345/87

(57) ABSTRACT

An imaging display apparatus comprises: a liquid-crystal display element; and a imaging unit, the liquid-crystal display element displaying an image alternately with respect to the imaging unit imaging a subject. The element comprises sets of pixels and a color filter that filters at least three colors, each of the sets of pixels corresponding to one of the colors, and the imaging unit does not have a color filter. The apparatus comprises: a section that controls transmittance such that only light entering one of the sets of pixels passes through the liquid-crystal display element, wherein the transmittance control is switched at a predetermined timing between the sets of pixels; a section that controls imaging of the imaging unit synchronous with the timing; a section that generates color image data by using a plurality of image data sets, each corresponding to one of the colors, and being obtained by imaging the subject.

### BACKGROUND OF THE INVENTION

1. Field of the Invention

The present invention relates to an imaging display apparatus which has a liquid-crystal display element and an imaging unit disposed behind the liquid-crystal display element and which alternately performs displaying of an image on the liquid-crystal display element and capturing of an image of a subject situated at the front of the liquid-crystal display element.

2. Description of the Related Art

In association with recent proliferation of the Internet and portable cellular phones, various services utilizing network lines associated with them have already been started. Among these services, interactive services, such as videoconferencing and a videophone calls, which are to be used for establishing communication while viewing facial expression of a person on the other side, have become prevalent. In this interactive service, an imaging display apparatus constituted of a combination of a camera with a display is used.

The dominant structure of currently-diffused imaging display apparatus is such that a camera and a display are separated from each other; for example, a structure in which a camera is mounted on top of the display. According to this structure, in a situation where a conversation is carried on with the person on the other side while the person's face is being displayed on the display, if the speaker looks into the face of the person on the other side appearing on the display, an image of the speaker who faces a position slightly lower than the camera is displayed on the display of the person on the other side. For this reason, the users cannot look directly at each other; namely, the users fail to establish and maintain eye contact.

In order to solve this problem, there has been put forward an imaging display apparatus having a structure in which a camera is disposed on the back of the liquid-crystal display by way of an optical shutter which can be switched between a transparent state and an opaque state by means of switching on/off of a voltage and in which the face of a speaker is captured through the liquid-crystal display (see JP-A-2002-94955). The technique described in JP-A-2002-94955 is for alternately performing displaying of an image on a liquid-crystal display and capturing of the image of the subject situated at the front of a liquid-crystal display through use of a camera. As result, the imaging display apparatus that enables exchange of eye contact is realized.

### SUMMARY OF THE INVENTION

However, the imaging display apparatus described in JP-A-2002-94955 is based on the premise that the device uses three types of light sources which emit red light, green light, and blue light; and is further based on use of a liquid-crystal display not having any color filters. This device cannot be manufactured through use of the currently-most-prevalent color liquid-crystal display. Consequently, manufacturing costs increase because a different LCD is required that is not the currently-most-prevalent color liquid-crystal display.

The present invention has been conceived in view of the circumstances and aims at providing an imaging display apparatus which can keep manufacturing costs low while enabling capturing of color images and display of color images.

An imaging display apparatus of the present invention is directed toward a liquid-crystal display element having a front face and a back face, and including, a plurality of sets of pixels, and a color filter capable of filtering at least three colors, wherein each of said plurality of sets of pixels corresponds to one of said at least three colors; at least one imaging unit adjacent to the back face of the liquid-crystal display element, wherein said at least one imaging unit is not capable of filtering any of said at least three colors, said liquid-crystal display element displaying an image alternately with respect to said at least one imaging unit imaging a subject adjacent to the front face of the liquid-crystal display element; a light transmittance control section that controls transmittance such that only light entering one of the plurality of sets of pixels passes through the liquid-crystal display element when the subject is imaged by said at least one imaging unit, wherein the transmittance control is switched at a timing between said sets of pixels; an imaging control section that controls imaging of said at least one imaging unit synchronously with the timing of the transmittance control; a color image data generation section that generates color image data by using a plurality of image data sets, each of which corresponds to one of said at least three colors in the color filter, and said plurality of image data sets being obtained by imaging the subject with said at least one imaging unit; and an output section that outputs the color image data generated by the color image data generation section.

By means of this configuration, there can be provided an imaging display apparatus capable of realizing, e.g., a videophone or the like, through use of a liquid-crystal display element having color filters and an imaging unit not having any color filters. Although the imaging unit does not have any color filters, color image data can be generated by utilization of the color filters of the liquid-crystal display element. Hence, an imaging display device which realizes display of a color image and capturing of a color image of a subject can be provided at low cost.

According to the present invention, there is also provided an imaging display apparatus, said at least one imaging unit comprising a plurality of imaging units, the imaging display apparatus further comprising: a position detection section that detects the position of the subject based on said plurality of image data sets, said plurality of image data sets being obtained by imaging the subject with each of said plurality of imaging units; and a imaging unit selection section that selects one of said plurality of imaging units according to a position of the subject detected by the position detection section, wherein the color image data generation section generates the color image data by using said plurality of image data sets from the selected one of said plurality of imaging units.

According to the present invention, there is also provided an imaging display apparatus, said at least one imaging unit comprising a plurality of imaging units, wherein the color image data generation section generates a plurality of color image data sets, wherein each of said color image data sets is obtained by using said plurality of image data sets, obtained by imaging the subject with each of said plurality of imaging units, and the color image data generation section generates a three-dimensional color image based on said plurality of color image data sets; and the output section outputs the three-dimensional color image generated by the color image data generation section.

According to the present invention, there is also provided an imaging display apparatus, which displays, on the liquid-crystal display element, an image based on the color image data from the color image date generation section.

### BRIEF DESCRIPTION OF THE DRAWINGS

FIG. 1 is a cross-sectional view of a schematic configuration of an imaging display apparatus to be used for describing an embodiment of the present invention;

FIG. 2 is a block diagram of the schematic configuration of the imaging display apparatus to be used for describing the embodiment of the present invention;

FIG. 3 is a view for describing operation of the imaging display apparatus to be used for describing the embodiment of the present invention;

FIGS. 4A to 4C are views showing a state in which light has passed through only R color filters of a liquid-crystal displaying element of the imaging display apparatus to be used for describing the embodiment of the present invention; and

FIG. 5 is a view showing the configuration of an imaging display apparatus to be used for describing the embodiment of the present invention when three imaging units are provided.

### DETAILED DESCRIPTION OF THE INVENTION

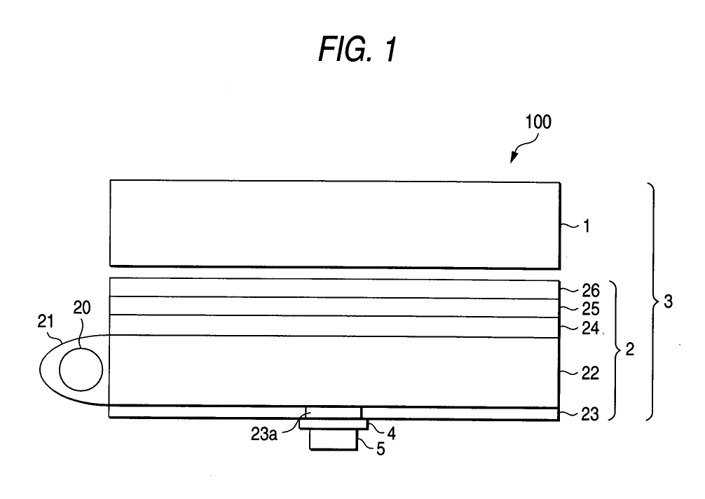

FIG. 1 is a view showing a cross-sectional view of a brief configuration of an imaging display apparatus for describing an embodiment of the present invention.

An imaging display apparatus 100 comprises a liquid-crystal display device 3 having a liquid-crystal element 1, and a backlight unit 2 disposed behind the liquid-crystal display element; a shutter 4; and an imaging unit 5. The shutter 4 is disposed behind the backlight unit 2, and the imaging unit 5 is disposed behind the shutter 4.

The imaging display apparatus 100 alternately performs display of an image through use of the liquid-crystal element 1, and capturing of an image of a subject situated at the front of the liquid-crystal display element 1 through use of the imaging unit 5. The imaging display apparatus 100 is utilized as videophones by means of which two users situated at remote locations have a conversation while each views the other's face displayed on the liquid-crystal display element 1. To this end, the imaging display apparatus 100 is equipped with an unillustrated microphone and an unillustrated speaker. Such microphone and speaker are well-known in the art, and their illustration is omitted for the sake of clarity.

The liquid-crystal display element 1 has a filter that filters three colors; that is, red (R), green (G), and blue (B), and can display a color image by means of this filter. The number of colors filtered by the filter is not limited to three. A filter that filters another set of three colors; that is, Ce (cyan), Mg (magenta), and Ye (yellow), or a filter that filters four or more colors may also be used.

No specific limitations are imposed on a liquid-crystal material used for the liquid-crystal display element 1. However, for instance, a liquid-crystal compound showing a nematic phase or a smectic phase is used. Further, liquid-crystal compounds described in pp. 154 to 192 and pp. 715 to 722 of “Liquid-crystal Device Handbook” (edited by the 142^{nd} committee of Japan Society for the Promotion of Science, Daily Industrial Newspaper Co., Ltd., 1989) can also be used. Alternatively, fluorine-substituted host liquid-crystal suitable for activating a TFT can also be used.

Further, liquid crystal may have negative dielectric constant anisotropy. As a result of combination of liquid crystal having negative dielectric constant anisotropy with a vertically-oriented film, liquid crystal is oriented in the vertical direction when supplied with no voltage, whereby the liquid crystal permits transmittance of light without absorbing it. When supplied with a voltage, liquid-crystal molecules remain tilted horizontally, and hence a difference in refractive index arises between the liquid crystal and polymer, thereby inducing scattering of light. Specifically, the liquid crystal is transparent when supplied with no voltage, but the liquid crystal enters a light scattering mode when supplied with a voltage.

In order to realize a crystal assuming negative dielectric constant anisotropy, there must be achieved a structure in which dielectric constant anisotropy becomes greater along the brachyaxis of liquid-crystal molecules. For instance, the crystal having negative dielectric constant anisotropy includes a crystal described on pp. 4 to 9 of “Monthly Display” (April, 2000) and a crystal described in Synlett, pp. 389 to 396, Vol. 4, 1999. Of these crystals, a crystal which has a fluorine-based substituent and negative dielectric constant anisotropy is preferable. For instance, liquid crystal available from Merck Co., Ltd. (MLC-6608, 6609, and 6610) can be mentioned.

With a view toward changing physical properties of liquid crystal with in a desired range (e.g., with a view toward bringing a temperature range of a liquid-crystal phase within a desired range), a compound showing no liquid-crystal characteristic may be added to the liquid crystal. The liquid crystal may be caused to contain a compound, such as a chiral compound, an UV-radiation absorbing agent and an oxidation inhibitor. Such additives include, e.g., chiral agents for TN and STN described in pp. 199 to 202 of “Liquid-crystal Device Handbook” (edited by the 142^{nd} committee of Japan Society for the Promotion of Science, Nikkan Kogyo Shimbun, Ltd., 1989).

The backlight unit 2 comprises a Cold Cathode Fluorescent Lamp (CCFL) 20; a lamp reflector 21; a light guide plate 22; a reflection plate 23; a scattering sheet 24; and prism sheets 25, 26.

The lamp reflector 21 causes the light emitted from the CFL 20 to enter the light guide plate 22 through reflection. The light guide plate 22 guides the light emitted from the CFL 20 to the entire surface of the liquid-crystal display element 1. The scattering sheet 23 reflects the light that has traveled downward within the light guide plate 22 in the drawing. The scattering sheet 24 diffuses upwardly the light that has traveled from the light guide plate 22 in an upward direction in the drawing. The prism sheets 25, 26 change the angle of the light diffused by the scattering sheet 24 such that the light becomes a collimated light which travels upward in the drawing.

The shutter 4 is constituted of a polymeric scattering-type liquid-crystal layer and is provided so as to seal a hole 23a formed in the reflection plate 23. The shutter 4 is attached to the imaging unit 5.

When polymeric scattering-type liquid crystal is supplied with no voltage, optical anisotropic characteristics of liquid-crystal droplets within a polymeric layer are arranged at random, and hence the liquid crystal exhibits an optically-opaque state. When the polymeric scattering-type liquid crystal is supplied with a voltage, the optical anisotropic characteristics of liquid-crystal droplets within the polymeric layer are changed into a fixed arrangement, and hence the liquid crystal enters an optically transparent state. Likewise, when supplied with no voltage, the shutter 4 enters a transparent state, whereupon the light entering the liquid-crystal display element 1 from the front thereof (i.e., an upward direction in the drawing) is taken into a hole 23a, thereby causing the light to enter the imaging unit 5. When supplied with a voltage, the shutter 4 enters an opaque state, thereby preventing the light emitted from the CFL 20 from entering the imaging unit 5 and reflecting the light emitted from the CFL 20 upwardly in the drawing.

The imaging unit 5 images the subject located at the front face of the liquid-crystal display element 1 (i.e., at an upward position in the drawing) through use of an optical system, such as a photographing lens, and an imaging element, such as a CCD image sensor, and outputs an analogue imaging signal. The optical system of the imaging unit 5 is designed such that the subject is brought into focus. The imaging element incorporated into the imaging unit 5 has no color filters and captures a monochrome image of the subject. Since signal processing for enhancing color separation is performed by a signal processing section 6, an imaging unit-which has a single color filter of a single color provided on an imaging surface of an imaging element so as to cover the entire surface of the imaging element—may also be employed as the imaging unit 5.

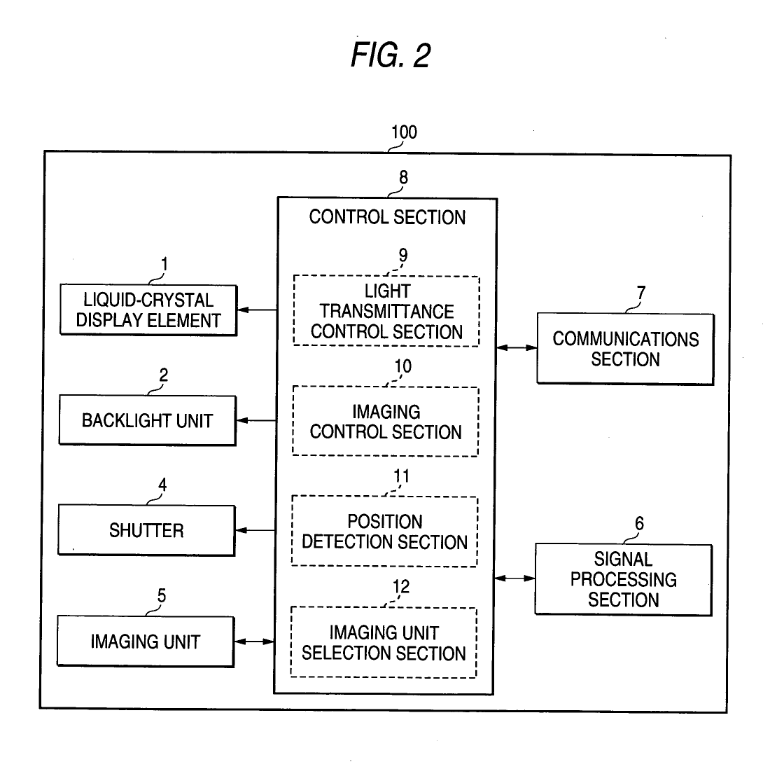

FIG. 2 is a block diagram showing a schematic configuration of the imaging display apparatus for describing the embodiment of the present invention.

The imaging display apparatus 100 comprises the liquid-crystal display element 1; the backlight unit 2; the shutter 4; the imaging unit 5; the signal processing section 6; a communications section 7; and a control section 8 which is chiefly constituted of a processor, the processor operating in accordance with a predetermined program, and controls the entirety of the imaging display apparatus.

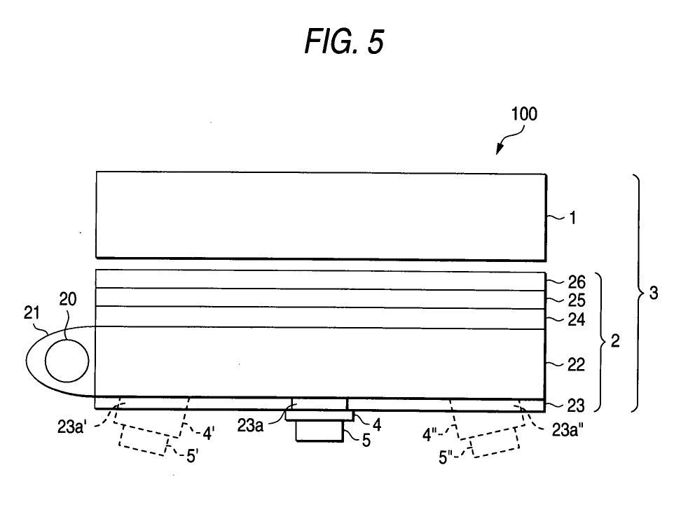

Position detection section 11 and imaging unit section 12 are optional features that are discussed in greater detail below with respect to the second embodiment in FIG. 5. These features are not required for operation of the first embodiment described below.

The control section 8 comprises a light transmittance control section 9 that, when the image of the subject is imaged by the imaging unit 5, performs the function of transmittance control such that only light entering one of the sets of pixels, each of the sets corresponding to one of R, G, B, passes through the liquid-crystal display element 1 in which the transmittance control is switched at a predetermined timing between the sets of pixels in accordance with a color selecting signal from the light transmittance control section 9.

The control section 8 also comprises an imaging control section 10 that performs the function of controlling imaging operation of the imaging unit 5 at a timing synchronous with the predetermined timing in response to an imaging control signal from the imaging control section 10. In addition, the control section 8 performs the function of activation-deactivation control of the CFL 20 of the backlight unit 2 in accordance with an activation-deactivation signal from the control section 8, control of application of a voltage to the shutter 4 in accordance with a voltage signal from the control section 8, and control of a communications timing of the communications section 7.

The signal processing section 6, serving as a color image data generation section, performs the function of digitizing three imaging signals which have been captured by the imaging unit 5 in accordance with the signals from the control section 8 as described above. These three signals correspond to the respective R, G, and B colors. The signal processing section 6 also performs the function of generating color image data from the three sets of digitized image data. For example, the color image data corresponds to data to be used for generating a color image and image data formed as a result of imparting to one pixel three sets of color data; that is, R color data, G color data, and B color data. As mentioned above, when one filter is provided on the imaging surface of the imaging element, the signal processing section 6 can also perform the function of signal processing for enhancing color separation by utilization of the filter. The signal processing section 6 digitizes sound input into an unillustrated microphone.

Here, the thus-generated color image data are transmitted from the communications section 7, which functions as an output section, to the imaging display apparatus 100 of the other party serving as a remote user. The communications section 7 also transmits the digitized sound input to the other party. For example, but not by way of limitation, the digitized sound may be received by the other party in a speaker or headphone or the like of a mobile communications device.

The communications section 7 establishes communication with the imaging display apparatus 1 of the other party, by way of a network, such as the Internet.

Operation of the imaging display apparatus 100 will now be described.

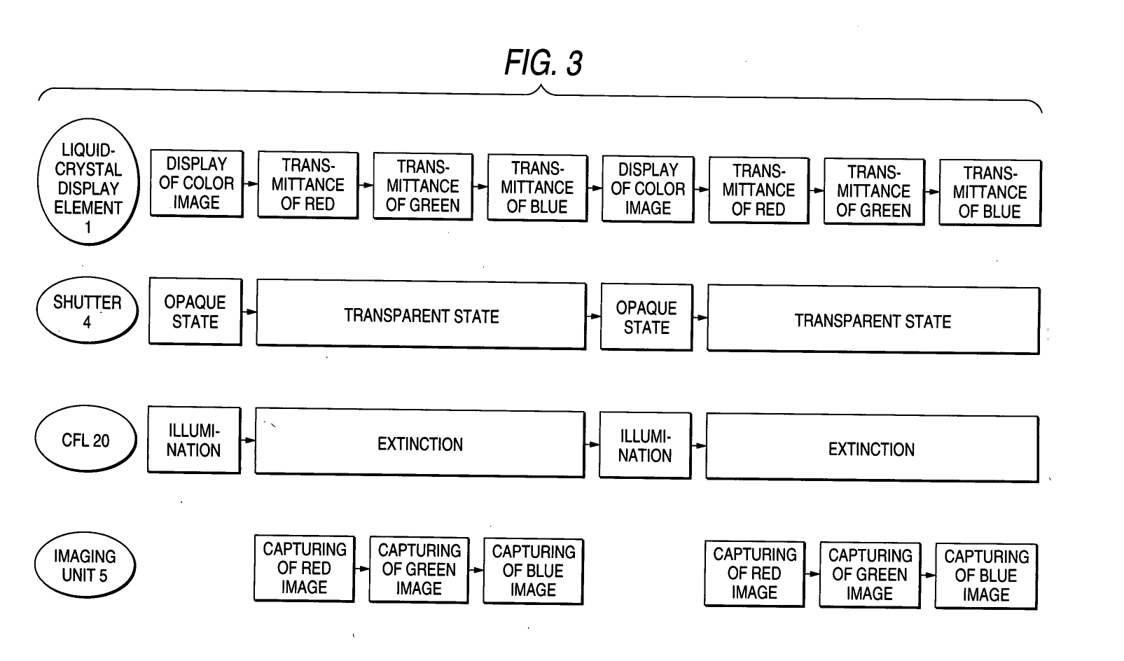

FIG. 3 is a view for describing operation of the imaging display apparatus to be used for describing the embodiment of the present invention. In the drawing, an object of operation is indicated by an oval figure, and the status of the object of operation is indicated by a rectangle in time sequence from left to right.

When the liquid-crystal display element 1 is caused to display an image, the control section 8 brings the shutter 4 into a closed state (i.e., an opaque state) without application of a voltage and also brings the CFL 20 into an illuminated state, to thus display, on the display surface of the liquid-crystal display element 1, an image based on color image data transmitted from the imaging display apparatus 100 of the other party by way of the communications section 7. At this time, the shutter 4 is closed, and the CFL 20 remains illuminated. Therefore, the imaging display apparatus 100 operates as a translucent color liquid-crystal display and displays a color image of the other party on the display surface of the liquid-crystal display element 1.

When an image of the subject is captured, the control section 8 applies a voltage to the shutter 4, thereby bringing the shutter 4 into an open state (i.e., a transparent state) and bringing the CFL 20 into an extinguished state. A voltage is applied to the liquid-crystal layer of the liquid-crystal display element such that only the light that enters the pixels corresponding to the R color filter from the subject side is caused to pass through the liquid-crystal layer. After lapse of a predetermined time, a voltage is applied to the liquid-crystal layer of the liquid-crystal display element such that only the light that enters the pixels corresponding to the G color filter from the subject side is caused to pass through the liquid-crystal layer. After lapse of a predetermined time, a voltage is applied to the liquid-crystal layer of the liquid-crystal display element such that only the light that enters the pixels corresponding to the B color filter from the subject side is caused to pass through the liquid-crystal layer. As a result, as shown in FIG. 3, the state of the liquid-crystal display element 1 makes a transition in the sequence of a state in which only red light passes through the liquid-crystal layer (i.e., transmittance of red), a state in which only green light passes through the liquid-crystal layer (i.e., transmittance of green), and a state in which only blue light passes through the liquid-crystal layer (i.e., transmittance of blue).

The control section 8 commands the imaging unit 5 to capture an image every time a voltage is applied to the liquid-crystal layer in the above-mentioned manner. In accordance with a command from the control section 8, in the imaging unit 5, three colors of light having passed through the RGB color filter are captured separately and capturing of an image of the subject is separately performed three times (i.e., capturing of a red image, capturing of a green image, and capturing of a blue image, which are shown in FIG. 3). The three imaging signals output from the imaging unit 5 are input to the signal processing section 6, where the three imaging signals are digitized. The thus-digitized three sets of image data are merged together, whereby a single set of color image data is generated. The thus-generated color image data are transmitted from the communications section 7 to the imaging display apparatus 100 of the other party. A color image based on the color image data is displayed on the display screen of the imaging display apparatus 100 of the other party.

The control section 8 sequentially performs display of the image, capturing of the image of the subject, and control of transmission of the color image data at an operation timing of about one-thirtieth of a second. As a result, two users who use the imaging display apparatus 100 can communicate while viewing the face of the other party appearing on the display screen.

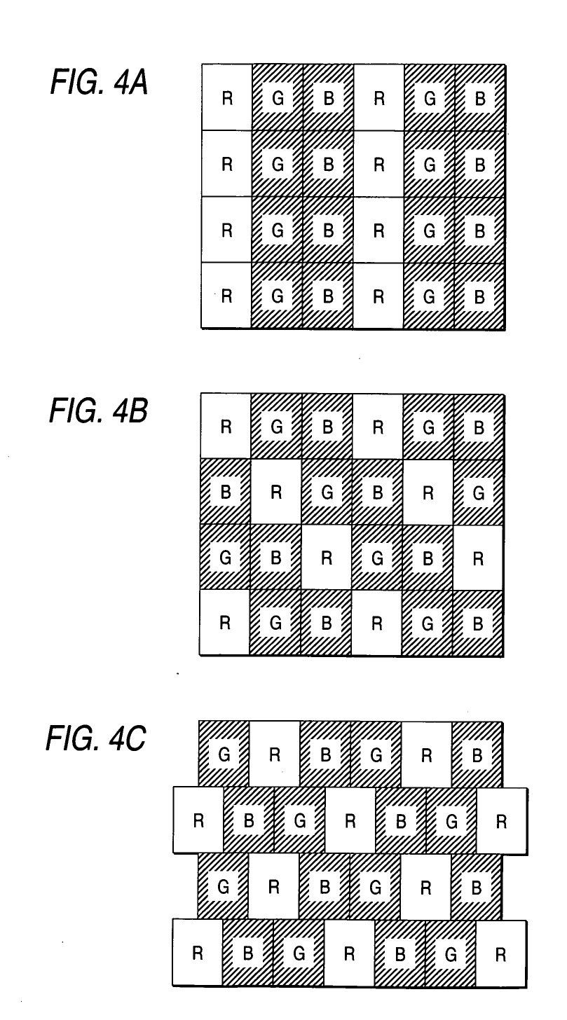

When the control section 8 has applied a voltage to the liquid-crystal layer of the liquid-crystal display element 1 such that only the light entering the pixels corresponding to the R color filter is caused to pass through the liquid-crystal layer, the liquid-crystal display element 1 has the same function as that shown in FIGS. 4A to 4C in which areas corresponding to the G and B color filters are dark. In FIG. 4, FIG. 4A shows color filters arranged in a stripe pattern; FIG. 4B shows color filters arranged in a mosaic pattern; and FIG. 4C shows color filters arranged in a delta pattern.

The focal point of the optical system of the imaging unit 5 is designed so as to be distant from focal point of the color filter of the liquid-crystal display element 1. Therefore, when the liquid-crystal display element 1 is viewed from the imaging unit 5, the color filter of the liquid-crystal display element 1 is out of focus, and the filter appear to be blurred. When in this state the image of the subject is captured through use of the imaging unit 5, there is obtained an imaging signal which is the same as that obtained when the image of the subject is captured as if one red filter were placed on the imaging surface of the imaging element, because the color filter of the liquid-crystal element 1 are blurred. Similarly, an imaging signal which is the same as that obtained when the image of the subject is captured while green and blue filters are placed on the imaging surface of the imaging element. In the imaging display apparatus 100, the signal processing section 6 merges the three sets of image data obtained through the red, green, and blue filters, thereby imparting the CCD of the imaging unit 5 with the same function as that achieved by a CCD of a three-plate type.

As mentioned above, according to the imaging display apparatus 100, the liquid-crystal display element 1 is caused to act as if it had three separate color (RGB) filters, thereby merging the image data pertaining to the subject captured by way of the three colors of filters. As a result, color image data can be generated even when the imaging unit 5 does not have any separate color filters.

According to the imaging display apparatus 100, a common liquid-crystal display device having a color filter can be used as the liquid-crystal display device 3. Further, an imaging element having no color filters can be utilized as an imaging element, such as a CCD. Therefore, costs incurred in manufacturing the imaging display apparatus 100 can be kept low.

In the above descriptions, a backlight of side light type having the light guide plate 22 is used as the backlight unit 2 of the liquid-crystal display device 3. However, a hollow backlight unit not having the light guide plate 22 can also be used. In such a case, it is better to place the shutter 4 so as to close a hole formed in a reflection plate disposed behind a hollow backlight unit or to place the imaging unit 5 in a hollow section of the hollow backlight unit. In the latter case, the imaging unit 5 must be encased within a plain white box so as to reflect the light emitted from a CFL.

A reflection-type liquid-crystal display device can also be used as the liquid-crystal display device 3. In such a case, it is better to place the shutter 4 so as to close a hole formed in a reflection plate of the reflection-type liquid-crystal display device.

In FIG. 1, the shutter 4 is provided so as to close the hole 23a formed in the reflection plate 23. However, the shutter 4 may be formed so as to extend over the entire surface of the light guide plate 22 without use of the reflection plate 23, and the shutter 4 may be caused to act as the reflection plate 23 when an image is displayed on the liquid-crystal display element 1. Moreover, when the image of the subject is captured by the imaging unit 5, the shutter may be caused to act as a shutter which produces a translucent region in a mounted portion of the imaging unit 5 or the entirety of the imaging unit 5. By means of this configuration, the reflection plate 23 and the shutter 4 can be embodied as a single member, thereby resulting in a cost reduction. Further, when the shutter 4 is formed over the entirety of the light guide plate 22, the imaging unit 5 can be used while being moved, as required.

In the above descriptions, the shutter 4 is embodied from a polymer dispersed liquid crystal. However, the shutter 4 may be embodied as one capable of performing mechanical opening and closing actions. For instance, in FIG. 1, a member identical with the reflection plate 23 may be loaded and unloaded between the hole 23a and the imaging unit 5, thereby controlling the opening and closing actions.

In FIG. 1, a lens may be interposed between the liquid-crystal display element 1 and the light guide plate 22. By means of this configuration, the lens collects the light entering from the subject side, so that an image brought into the focus of the imaging unit 5 can be captured. Use of a Fresnel lens as a lens enables an attempt to make the imaging display apparatus 100 compact.

Provision of a plurality of imaging units 5 (e.g., three imaging units) on the back of the reflection plate 23 is also possible. FIG. 5 shows an example configuration of the imaging display apparatus 100 achieved in such a case. In this case, all the imaging units are controlled by the control section 8.

In the imaging display apparatus 100 shown in FIG. 5, shutters 4′, 4″ are placed so as to close holes 23a′, 23a″ formed in the reflection plate 23. Imaging units 5′, 5″ are provided on the back of the shutters. When the photographing direction of the imaging unit 5 is taken as a reference, the imaging units 5′, 5″ are arranged at a predetermined angle with reference to the photographing direction. However, rather than being arranged at an inclination, the imaging units 5′, 5″ may be arranged in the same direction as that in which the imaging unit 5 is oriented. Alternatively, the imaging unit 5, 5′, and 5″ may be made movable.

When the three imaging units are provided as shown in FIG. 5, the functions of the imaging display apparatus 100 are changed to (1) or (2) which are provided below.

(1) The control section 8 comprises a position detection section 11, and the position detection section 11 detects the position of the subject on the basis of the image data (obtained as a result of digitization of three imaging signals corresponding to RGB colors) obtained as a result of three imaging units having captured images. One is selected from the three imaging units according to the detected position in accordance with an imaging unit selecting signal from the position detection section 11, the imaging unit selecting signal being generated in response to a position detection signal from the imaging control section 10. In addition, the control section 8 comprises an imaging unit selection section 12, and the signal processing section 6 generates color image data through use of the image data obtained as a result of an image being captured by the imaging unit selected by the imaging unit selection section 12.

(2) Through use of the image data obtained as a result of the three imaging units 5, 5′, and 5″ having captured images, the signal processing section 6, serving as a color image data generation section, generates three sets of color image data corresponding to the three imaging units 5, 5′, and −5″ Three-dimensional color image data to be used for generating a three-dimensional color image are produced from the thus-generated three sets of color image data. The communications section 7, serving as an output section, transmits to the imaging display apparatus of the other party the three-dimensional color image data generated by the signal processing section 6.

Operation of the imaging display apparatus 100 to be performed in (1) will now be described.

In this case, when the CFL 20 is desired to be extinguished by means of opening the shutter 4, the image control section 10 in the control section 8 subjects the three imaging units 5, 5′, and 5″ to the above-described image-capturing control. Imaging signals obtained as a result of the image-capturing control operation are temporarily stored in unillustrated internal memory. In the meantime, the signal processing section 6 generates three-dimensional information about the subject by utilization of the image data obtained as a result of the three imaging units 5, 5′, and 5″ having captured respective images in accordance with the image-capturing control. The three-dimensional information is provided to the control section 8. On the basis of the thus-provided three-dimensional information, the position detection section 11 in the control section 8 detects the position of the subject (e.g., the position of a face), and an imaging unit suitable for the thus-detected position is selected in the imaging unit selection section 12. The imaging unit suitable for the detected position is an imaging unit which can capture an image of the subject's face from the front thereof. The control section 8 reads from the internal memory the imaging signal produced by the thus-selected imaging unit and inputs the imaging signal to the signal processing section 6, thereby causing the signal processing section 6 to generate color image data.

As a result, the image to be displayed on the imaging display apparatus of the other party can be changed to an optimum image in accordance with the position of the subject's face. Therefore, communication imparting no unusual feeling can be realized.

In the case of (2), after the image control section 10 in the control section 8 has subjected the three imaging units 5, 5′, and 5″ to the foregoing image-capturing control operation, the signal processing section 6 generates three sets of color image data corresponding to the three imaging units 5, 5′, and 5″ through use of the image data as a result of the three imaging units 5, 5′, and 5″ having captured respective images. The thus-generated three-dimensional color image data are transmitted to the imaging display apparatus of the other party from the communications section 7.

As a result, the image of the subject can be ascertained three-dimensionally.

The imaging display apparatus 100 may display, on the display surface of the liquid-crystal display element 1 of that imaging display apparatus 100, an image based on the image data obtained as a result of the imaging unit 5 having captured an image. In this case, images of the imaging display apparatus 100 which are captured at a predetermined timing are displayed in real time on the display surface, and hence the imaging display apparatus 100 can be caused to act as if it were a mirror.

According to the present invention, there can be provided an imaging display apparatus which can keep manufacturing costs low.

This application is based on Japanese patent application JP2003-325388, filed on Sep. 18, 2003, the entire content of which is hereby incorporated by reference, the same as if set forth at length.

1. An imaging display apparatus comprising:
a liquid-crystal display element having a front face and a back face, and including,
a plurality of sets of pixels, and
a color filter capable of filtering at least three colors, wherein each of said plurality of sets of pixels corresponds to one of said at least three colors;
at least one imaging unit adjacent to the back face of the liquid-crystal display element, wherein said at least one imaging unit is not capable of filtering any of said at least three colors, said liquid-crystal display element displaying an image alternately with respect to said at least one imaging unit imaging a subject adjacent to the front face of the liquid-crystal display element;
a light transmittance control section that controls transmittance such that only light entering one of the plurality of sets of pixels passes through the liquid-crystal display element when the subject is imaged by said at least one imaging unit, wherein the transmittance control is switched at a timing between said sets of pixels;
an imaging control section that controls imaging of said at least one imaging unit synchronously with the timing of the transmittance control;
a color image data generation section that generates color image data by using a plurality of image data sets, each of which corresponds to one of said at least three colors in the color filter, and said plurality of image data sets being obtained by imaging the subject with said at least one imaging unit; and
an output section that outputs the color image data generated by the color image data generation section.

2. The imaging display apparatus according to claim 1, said at least one imaging unit comprising a plurality of imaging units, the imaging display apparatus further comprising:
a position detection section that detects the position of the subject based on said plurality of image data sets, said plurality of image data sets being obtained by imaging the subject with each of said plurality of imaging units; and
a imaging unit selection section that selects one of said plurality of imaging units according to a position of the subject detected by the position detection section,
wherein the color image data generation section generates the color image data by using said plurality of image data sets from the selected one of said plurality of imaging units.

3. The imaging display apparatus according to claim 1, said at least one imaging unit comprising a plurality of imaging units,
wherein the color image data generation section generates a plurality of color image data sets, wherein each of said color image data sets is obtained by using said plurality of image data sets, obtained by imaging the subject with each of said plurality of imaging units, and the color image data generation section generates a three-dimensional color image based on said plurality of color image data sets; and
the output section outputs the three-dimensional color image generated by the color image data generation section.

4. The imaging display apparatus according to claim 1, which displays, on the liquid-crystal display element, an image based on the color image data from the color date generation section.

5. An imaging display apparatus comprising:
a display device that displays an image, including (i) a plurality of sets of light transmitting devices and (ii) a filter device that filters at least three colors, each of said plurality of sets of light transmitting devices corresponding to one of said at least three colors;
at least one image device that images a subject positioned adjacent to a front side of said display device, said imaging device being located adjacent to a back side of the display device and not capable of filtering any of said at least three colors, wherein the display device displays said image alternately with respect to the imaging device imaging said subject;
means for controlling light transmittance so as to only allow light at said sets of light transmitting devices having a selected one of said at least three colors to pass through the display device when the subject is imaged during said timing, wherein the selected one of said at least three colors is switched at an timing by switching said sets of light transmitting devices;
means for controlling said imaging device synchronously with the timing;
means for generating color image data by merging a plurality of image data sets corresponding to said at least three colors in said filter device and obtained by imaging the subject with said at least one image device; and
means for transmitting the color image data generated by the means for generating to a remote user.

6. The imaging display apparatus according to claim 5, said at least one image device comprising a plurality of image devices, the imaging display apparatus further comprising:
means for detecting the position of the subject based on said plurality of image data sets, said plurality of image data sets being obtained by imaging the subject with each of said plurality of image devices; and
means for selecting one of said plurality of image devices according to a position of the subject detected by the means for detecting,
wherein the means for generating generates the color image data by using said plurality of image data sets from the selected one of said plurality of image devices.

7. The imaging display apparatus according to claim 5, said at least one image device comprising a plurality of image devices, the imaging display apparatus further comprising:
wherein the means for generating generates a plurality of color image data sets, wherein each of said color image data sets is obtained by using said plurality of image data sets, obtained by imaging the subject with each of said plurality of imaging units, and the means for generating generates a three-dimensional color image based on said plurality of color image data sets; and
the means for transmitting, to the remote user, the three-dimensional color image generated by the means for generating.

8. The imaging display apparatus according to claim 5, which displays, on the display device, an image based on the color image data from the means for generating.
